(19) United States
(12) Patent Application Publication
(10) Pub. No.: US 2024/0372326 A1
(43) Pub. Date: Nov. 7, 2024

(54) EXTERNAL-CAVITY DIODE LASER BASED ON VOIGT ANOMALOUS DISPERSION ATOMIC OPTICAL FILTER, AND METHOD THEREOF

(71) Applicant: PEKING UNIVERSITY, Beijing (CN)

(72) Inventors: Jingbiao CHEN, Beijing (CN); Anhong Dang, Beijing (CN); Zijie Liu, Beijing (CN); Tiantian Shi, Beijing (CN)

(21) Appl. No.: 18/651,575

(22) Filed: Apr. 30, 2024

(30) Foreign Application Priority Data
May 6, 2023 (CN) 202310504128.0

(51) Int. Cl. H01S 5/14; H01S 3/08; H01S 3/105; H01S 5/00; H01S 5/02326; H01S 5/024; H01S 5/028

(52) U.S. Cl. CPC H01S 5/141; H01S 3/08054; H01S 3/105; H01S 5/0064; H01S 5/02326; H01S 5/02415; H01S 5/028; H01S 2301/18

(57) ABSTRACT

The present application discloses an external-cavity diode laser based on a Voigt anomalous dispersion atomic optical filter. The laser includes: a laser diode coated with an anti-reflective coating, where the laser diode is provided with a temperature control module thereon; a collimation module, configured to perform collimation and expanding for the laser diode; the Voigt anomalous dispersion atomic optical filter, configured to filter laser light emitted from the laser diode, where a spectrum of laser light output from the laser depends on a transmission spectrum of the atomic optical filter; a reflective cavity mirror, configured to reflect the laser light filtered by the atomic optical filter back into a resonant cavity to form oscillation and produce stable laser light; a piezoelectric ceramic, assembled with the reflective cavity mirror and configured to fine-tune a cavity length of the laser to achieve tuning of the laser light.

### CROSS-REFERENCE TO RELATED APPLICATION

This application claims priority to Chinese Patent Application No. 202310504128.0, filed on May 6, 2023, which is hereby incorporated by reference in its entirety.

### TECHNICAL FIELD

The present application relates to the field of semiconductor laser technologies and, in particular to, an external-cavity diode laser based on a Voigt anomalous dispersion atomic optical filter, and a method thereof.

### BACKGROUND

As a high-quality ultra-narrowband optical filter, the Faraday anomalous dispersion atomic optical filter has undergone in-depth theoretical analysis and experimental research domestically and internationally since the 1990s. With the advantages of high transmittance, narrow bandwidth and a high noise suppression ratio, it is currently widely used in fields such as lidar, space and satellite optical communications.

An external-cavity diode laser with the Faraday atomic optical filter being taken as a frequency-selective device has an excellent characteristic of being immune to changes of the operating current and temperature of a laser diode. For a Faraday laser that has already normally operated, in a case that the operating current and the operating temperature of the laser diode are significantly changed, the frequency of output laser light will not significantly jump as long as the operating current of the Faraday laser remains above a threshold. For the Faraday laser which has been debugged, it can still operate near a target wavelength after operating for a long time. This method significantly improves the performance of the laser at low cost, and a new trail is blazed to provide a unique solution to the current situation where high-performance lasers cannot be built by using semiconductor laser diodes with poor performance.

However, the Faraday anomalous dispersion atomic optical filter uses the Faraday magneto-optic rotation effect for frequency selection, requiring that the direction of the magnetic field must be along a laser light transmission direction (optical axis direction). Traditional Faraday atomic optical filters generate magnetic field that is along the optical axis direction by placing permanent magnets at the left and right ends of a cylindrical atomic vapor cell. With this solution, on the one hand, the volume of the Faraday laser along the optical axis direction is increased and the minimum cavity length of the laser is limited; on the other hand, the generated magnetic field strength is relatively small. Another solution is to place permanent magnets around the cylindrical vapor cell. In this case, the total volume of the magnets and the vapor cell in the atomic optical filter is usually greater than 0.5 L, the generated magnetic field strength is less than 1000 Gauss, and the magnetic field uniformity is less than 90%, which hinders the further improvement in frequency stability of the laser light output by the Faraday laser. Therefore, the atomic optical filter is the main reason hindering the reduction of laser volume. Large-volume lasers also have problems such as relatively poor portability and mechanical stability.

### SUMMARY

The present application provides an external-cavity diode laser based on a Voigt anomalous dispersion atomic optical filter, and a method thereof. The present application realizes the laser by using the Voigt anomalous dispersion atomic optical filter, a laser diode that has a collimation and beam expanding module and a temperature control module and is coated with an anti-reflective coating, and a reflective cavity mirror assembled with a piezoelectric ceramic, and also realizes a wide range of laser light frequency selection by applying single frequency laser light stably output by the laser. Compared with the Faraday anomalous dispersion atomic optical filter, the magnet used in the Voigt anomalous dispersion atomic optical filter can generate a larger magnetic field with a smaller volume, thereby obtaining a narrower transmission bandwidth and a more stable transmission spectrum. Correspondingly, the Voigt laser has stronger frequency stability and resistance to external interference; in addition, the Voigt laser has a smaller size, better mechanical stability, and frequency stability than the mainstream Faraday laser, details of which can be referred to the description as follows.

In a first aspect, an external-cavity diode laser based on a Voigt anomalous dispersion atomic optical filter is provided according to an embodiment of the present application, where the Voigt laser includes:
a laser diode coated with an anti-reflective coating, which serves as a seed source of the Voigt laser and has a wide range of emitted wavelengths and a large divergence angle of emitted laser light;
a collimation module, including a collimating lens and a corresponding retaining structure, and configured to perform collimation for the laser diode;
the Voigt anomalous dispersion atomic optical filter, filtering laser light emitted by the laser diode, where laser light output by the Voigt laser depends on a transmission spectrum of the Voigt anomalous dispersion atomic optical filter;
a reflective cavity mirror with a reflectivity of 99.9%, reflecting the laser light filtered by the atomic optical filter back into a resonant cavity to form oscillation and produce stable laser light;
an integrated mechanical structure of the laser, mainly including a laser base, four side plates, and a cover plate, which are configured to fix elements in the laser and assemble respective elements into a whole.

Further, the temperature control module including a thermoelectric cooler (TEC) and a temperature feedback control circuit is used to adjust operating temperature of the laser diode, with temperature control accuracy of 0.01-0.1 degrees Celsius; the collimation module is used to collimate the laser light emitted by the laser diode, to enable a divergence angle of the emitted laser light to be reduced to 0.01-2°.

Further, the Voigt anomalous dispersion atomic optical filter includes:
an alkali-metal atom vapor cell, which is a cylindrical glass vapor cell filled with alkali-metal atoms therein;
a magnetic field generating apparatus, with two rectangular permanent magnets close to a side wall of the atomic vapor cell, where a magnetic field with uniformity of more than 95% can be generated in the atomic vapor cell along a direction perpendicular to a laser light transmission direction, and where magnetic field strength can vary between 100 and 4000 Gauss by controlling sizes and positions of the permanent magnets, and the magnetic field strength is preferably 3500 Gauss;
a temperature control module, which performs monitoring and feedback controlling on temperature of the alkali-metal atom vapor cell; where a control range of the temperature is 30-200 degrees Celsius, control accuracy of the temperature is 0.01-0.1 degrees Celsius, and the temperature is preferably 60-120 degrees Celsius;
a polarizing filter module, including two polarizing beam splitter elements whose polarization directions are orthogonal, where the polarizing beam splitter elements are respectively located on either sides of the alkali-metal atom vapor cell, and filter the laser light whose polarization direction is rotated under the magnetic field.

Further, a back of the reflective cavity mirror is affixed with a piezoelectric ceramic thereon, which can change a cavity length of the laser when the laser is operating and implement frequency adjustment of the output laser light. This process is referred to as a sweep process of the laser. A travel of the piezoelectric ceramic is 3.3 μm, and a range of the sweep is related to the cavity length and an operating wavelength of the laser.

In a second aspect, an implementing and frequency-selective method of an external-cavity diode laser based on a Voigt anomalous dispersion atomic optical filter is provided according to an embodiment of the present application, includes:
assembling a laser diode with a temperature control module and a collimation module onto a laser base, and adjusting a position of a lens in the collimation module, to enable a divergence angle of laser light emitted from the collimation module to reach a minimum;
assembling a mirror holder assembled with a reflective cavity mirror and a piezoelectric ceramic onto the laser base; changing a pitch of the reflective cavity mirror by adjusting a pitch of the mirror holder, to enable laser light reflected at the cavity mirror to return along an original path, so that feedback of a resonant cavity reaches a maximum, ensuring that the used laser diode can oscillate normally.

The Voigt anomalous dispersion atomic optical filter assembled with a temperature control module and a magnetic field generating apparatus is assembled onto the laser base, and the temperature control module is deactivated. Polarization directions of two polarizing beam splitters are set to be orthogonal. At this time, the loss of the resonant cavity is too large and the laser cannot oscillate.

A half-wave plate is placed between an atomic vapor cell and a second polarizing beam splitter, to enable part of the laser light to pass through the polarizing beam splitter to transmit towards the reflective cavity mirror, thereby reducing the loss of the resonant cavity. The pitch of the reflective cavity mirror is changed by adjusting the pitch of the mirror holder, to enable the laser light reflected at the cavity mirror to return along the original path, so that the feedback of the resonant cavity reaches a maximum, and the laser oscillates normally. However, at this time, the atomic optical filter does not play a role in frequency selection.

The half-wave plate is removed, the temperature control module of the atomic optical filter is activated to increase the temperature of the atomic vapor cell to an appropriate degree, and a polarization direction of the laser light whose frequency is near the atomic transition frequency rotates under the Faraday effect, to enable the laser light near the frequency to be emitted from the orthogonal polarizers, so that the loss of the resonant cavity diminishes, the laser re-oscillates and the frequency of the output laser light is near the atomic transition frequency.

By changing the voltage of the piezoelectric ceramic to change the thickness of the piezoelectric ceramic, thereby changing the cavity length of the laser, the output frequency of the laser can be changed. This method is a laser tuning method for the Faraday laser. The laser tunable range depends on a smaller one between the free spectral range of the laser and the transmission spectrum bandwidth of the atomic optical filter. If the free spectral range is large, it will be found during the laser tuning process that when the operating frequency exceeds the transmission spectrum bandwidth of the atomic optical filter, the loss in the laser cavity is too large and the laser is deactivated, therefore, the tunable range is the transmission spectrum bandwidth of the atomic optical filter. If the transmission spectrum bandwidth of the atomic optical filter is large, when the operating frequency exceeds a boundary of the free spectral range, the operating frequency will immediately jump to another boundary of the free spectral range.

The advantageous effects of the technical solution provided by the present application are:
1. the present application uses the Voigt anomalous dispersion atomic optical filter to replace the mainstream Faraday dispersion atomic optical filter as the frequency-selective device of the external cavity semiconductor laser, realizing the first Voigt-type external cavity diode laser;
2. in the present application, the volume of the vapor cell and the magnet in the Voigt atomic optical filter is much smaller than the volume of the vapor cell and the magnet in the mainstream Faraday atomic optical filter, and the volume of the laser is also smaller than that of the mainstream Faraday laser, which results in better mechanical stability, better frequency stability of output laser light, and better portability, playing an important role in laser technologies, optical communications, optical networks, quantum communications and other fields;
3. the strength of the magnetic field of the Voigt atomic optical filter of the present application is 0-4000 Gauss, which is much higher than the 1000 Gauss of the mainstream Faraday atom optical filter, so that a narrower transmission bandwidth and a more stable transmission spectrum can be obtained, thereby the Voigt laser has stronger frequency stability and resistance to external interference, greatly improving the performance of the semiconductor laser when it runs freely.

### BRIEF DESCRIPTION OF DRAWINGS

FIG. 1 is a schematic structural diagram of an external-cavity diode laser based on a Voigt anomalous dispersion atomic optical filter; in which:
1. laser diode with temperature control module; 2. collimating lens;
3. polarizing beam splitter; 4. neodymium iron boron permanent magnet;
5. alkali-metal atom vapor cell; 6. reflective cavity mirror;
7. piezoelectric ceramic; and
where the arrow in FIG. 1 is the direction of a magnetic field, and the path represented by a bold black line is a laser light transmission path.

FIG. 2 is a flowchart of an implementing method of a Voigt laser.

### DESCRIPTION OF EMBODIMENTS

In order to make the purposes, technical solutions and advantages of the present application clearer, embodiments of the present application will be described in further detail below.

By using an anomalous dispersion atomic optical filter based on the Voigt effect to replace the Faraday atomic optical filter as a frequency-selective device of an external cavity diode laser, the problems existing in the related technologies can be effectively improved. The Voigt magneto-optic rotation effect requires that the direction of the magnetic field be perpendicular to the direction of the optical axis. By placing two magnets close to each other to a side surface of a cylindrical vapor cell, magnets with a total volume of less than 0.1 L can generate a magnetic field with a magnetic field strength greater than 3500 Gauss and a magnetic field uniformity greater than 95%. The magnetic field can be increased to 3500 Gauss, the tunable range is wider than the Faraday atomic optical filter, and a suitable operating point can be found to achieve a transmission spectrum with a narrow bandwidth and high transmittance, thereby the Voigt laser (that is, the external-cavity diode laser based on a Voigt anomalous dispersion atomic optical filter) outputs laser light with better frequency stability and stronger resistance to interference, and the Voigt laser is small in volume so that the optical system is more compact. According to this kind of Voigt laser, the problem that the Faraday laser is large in volume has been solved, and the frequency stability is further improved. This kind of Voigt laser can operate stably for a long time, and can play a vital role in semiconductor laser-related fields such as optical communications, optical computing, lidar and so on. More importantly, the Voigt laser may become a key technology for compact optical frequency standards, thereby achieving major breakthroughs in fields such as quantum frequency transmissions, satellite navigations, high-speed information networks, and so on in our country.

### Embodiment 1

Reference may be made to FIG. 1 for an external-cavity diode laser based on a Voigt anomalous dispersion atomic optical filter. The diode laser includes elements as follows.

(1) A laser diode 1, having a temperature control module and coated with an anti-reflective coating. The laser diode 1 has an excited wavelength range of 760-795 nm, operating temperature of 15-40 degrees Celsius, maximum operating current of 200 mA, and maximum output power of 100 mW. The laser diode 1 has a window coated with the anti-reflective coating, and a reflectivity of the window is 1×104, which prevents the laser diode 1 from spontaneously generating an intra-cavity mode that affects the output performance of the laser. Laser light emitted from the laser diode 1 has a fast-axis divergence angle of 14-30° and a slow-axis divergence angle of 7-10°. A thermoelectric cooler is used in conjunction with a temperature control module to perform temperature control on the laser diode 1 with an accuracy of 0.1 degrees Celsius.

(2) A collimating lens 2, retained in a sleeve and configured to collimate and expand the laser light emitted from the laser diode 1. The collimated laser light has a divergence angle of 0.1° and a spot diameter of 2 mm, and a distance between an end face of the collimating lens 2 and an emission end face of the laser diode 1 is 4.57 mm.

(3) A Voigt anomalous dispersion atomic optical filter, mainly including two polarizing beam splitters 3 (a first polarizing beam splitter and a second polarizing beam splitter in the order from left to right in FIG. 1), an alkali-metal atom vapor cell 5, and two rectangular neodymium iron boron permanent magnets 4. The first and second polarizing beam splitters 3 are orthogonal to each other, and they are both coated with an anti-reflective coating, and have a transmittance greater than 91.3% and an extinction ratio greater than 10000:1.

The direction of the arrow in FIG. 1 represents the direction of a magnetic field B, a magnitude of the magnetic field B can vary in a range of 100-4000 Gauss and is 3500 Gauss preferably. The alkali-metal atom vapor cell 5 is further affixed with a temperature control module, which can achieve a temperature control effect with an accuracy of 0.01 degrees Celsius.

(4) A reflective cavity mirror 6, with a reflectivity of 99.9%. The laser light that reaches an end face of the reflective cavity mirror 6 returns along an original path to form a resonance so that laser light emission is achieved, with the laser light being emitted from the second polarizing beam splitter 3. A cavity length of the entire laser is the distance from the emission end face of the laser diode 1 to an end face of the reflective cavity mirror 6.

(5) A piezoelectric ceramic 7, assembled together with the reflective cavity mirror 6, which can be configured to fine-tune the cavity length to achieve tuning of the laser light. The piezoelectric ceramic has a travel of 3.3 μm and a maximum voltage of 200 V, which meets the tuning requirements of the laser.

Further, the external-cavity diode laser based on the Voigt anomalous dispersion atomic optical filter further includes a laser housing and a base (not shown in the figure), and all elements are installed on the base.

### Embodiment 2

The solution in Embodiment 1 is further introduced below, which can be referred to the following description for details.

FIG. 1 is a principle diagram of a Voigt laser designed according to an embodiment of the present application. The laser includes: a laser diode 1, a collimating lens 2, a Voigt anomalous dispersion atomic optical filter (the device includes: polarizing beam splitters 3, permanent magnets 4 and an alkali-metal atom vapor cell, a reflective cavity mirror 6, and a piezoelectric ceramic 7.

The embodiment of the present application is described by taking an example where the laser diode 1 has a typical wavelength of 790 nm and a gain range of a 760-795 nm wavelength. In specific implementations, other types of laser diodes can also be selected, for example, a laser diode with an 860 nm wavelength serving as a typical wavelength can be selected, which is not limited in the embodiment of the present application.

A thermoelectric cooler is placed at a position close to a lower part of the laser diode, where the thermoelectric cooler has a nominal voltage of 12 V and a cooling power of 76.3 W, a cold side thereof is in contact with a copper base for fixing the laser diode, and a hot side thereof is in contact with the laser base. On the one hand, the copper base is configured to fix the laser diode, on the other hand, it is used to increase a contact area between the laser diode and the thermoelectric cooler, thereby increasing the heat dissipation of the laser diode. The thermoelectric cooler and a thermistor that is placed inside the copper base are connected to an external temperature control circuit, playing a role of temperature detection and control.

The alkali-metal atom vapor cell of the Voigt anomalous dispersion atomic optical filter in the embodiment of the present application is described by taking an ⁸⁷Rb atom vapor cell without buffer gas as an example. In specific implementations, other types of atomic vapor cells can also be selected, which is not limited in the embodiment of the present application. For example, a rubidium atom vapor cell is 10 mm in diameter and 30 mm in length, made of quartz, the vapor cell is coated with an anti-reflective coating at both ends thereof, and the transmittance of the vapor cell to laser light with a wavelength of 780 nm can reach 96%. The rubidium atom vapor cell, a magnetic field generating apparatus, a temperature control module and the two polarizing beam splitters 3 are assembled together by a self-designed housing, with a length of 60 mm in the laser light propagation direction. After the distance of 4.57 mm between the collimating lens and the laser diode and the distance between the cavity mirror and the Voigt anomalous dispersion atomic optical filter are further taken into consideration, the embodiment of the present application is explained by taking an example where the cavity length of the laser is 220 mm, and other sized cavity lengths can be chosen in specific implementations.

Further, when the magnetic field strength is 3500 Gauss and the temperature of the vapor cell is 75 degrees Celsius, the output wavelength of the Voigt laser should be 780.255 nm.

Further, in a case where the laser is operating stably, the output wavelength of the laser remains basically unchanged and the laser always maintains a single-mode output, when the current of the laser diode is changed. During the current of the laser diode changes from 70 mA to 150 mA, the change of the output wavelength of the laser is ±0.5 pm, and in the process of current change, the laser maintains a single longitudinal mode output.

The reflective cavity mirror 6 is affixed to the piezoelectric ceramic 7. By changing the voltage applied on the piezoelectric ceramic, the thickness of the piezoelectric ceramic is changed, and in turn the cavity length of the laser is changed, thereby the tuning of the laser is achieved. The piezoelectric ceramic has a maximum voltage of 200 V and a maximum travel of 3.3 μm which is greater than half of the output wavelength of the laser. Thus the tunable range can reach a maximum, which is 680 MHz when the cavity length is 220 mm. The reflective cavity mirror 6 and the piezoelectric ceramic 7 are affixed together to the mirror holder. The mirror holder can be a pitch-adjustable mirror holder with a screw or a pitch-adjustable mirror holder without a screw. The pitch-adjustable mirror holder without a screw changes the pitch of the reflective cavity mirror by pillowing a steel plate. In general, the mirror holder with a screw is more convenient to adjust, while the mirror holder without a screw has better mechanical stability. In an implementation, the mirror holder without a screw is preferred.

### Embodiment 3

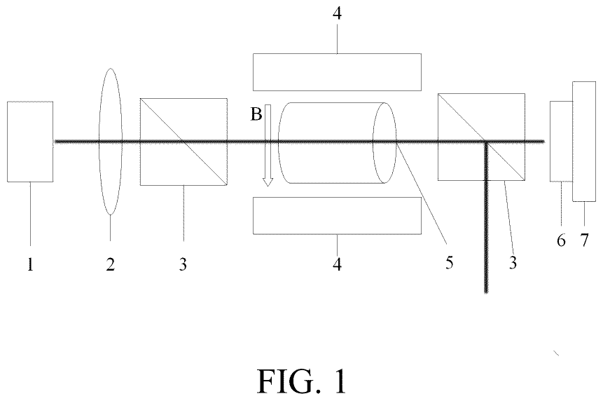

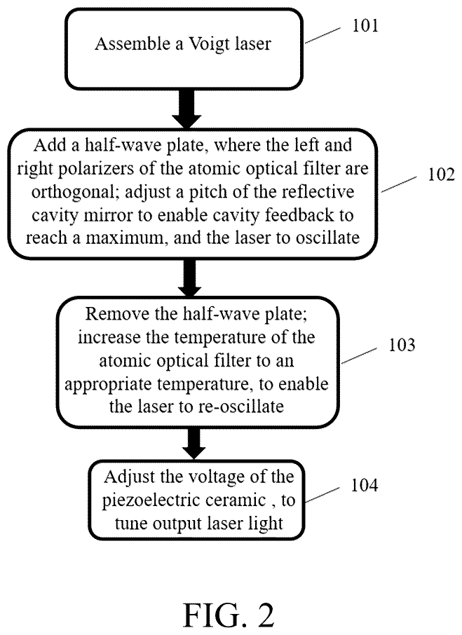

FIG. 2 is an implementing and tuning method of the Voigt laser mentioned above. The method includes the steps as follows.

Step 101, assemble a laser diode, a thermistor and a thermoelectric cooler onto a copper base, assemble a temperature control module, a magnetic field generating apparatus, an atomic vapor cell filled with ⁸⁷Rb and two polarizing beam splitters 3 into an atomic optical filter, affix a reflective cavity mirror 6 and a piezoelectric ceramic 7 to a mirror holder, install the copper base assembled with the laser diode, the atomic optical filter, and the mirror holder assembled with the reflective cavity mirror 6 onto a laser base; set polarization directions of the two polarizing beam splitters 3 to be orthogonal, in this case, the laser light cannot pass through the atomic optical filter, the laser is deactivated, and the output power of the laser is 0.

Step 102, add a half-wave plate between the atomic vapor cell and a second polarizing beam splitter 3, to enable part of the laser light emitted by the laser diode to pass through the second polarizing beam splitter 3; change a pitch of the mirror holder by pillowing a steel plate to adjust the feedback of the laser, to enable the laser light to return along an original path at an end face of the reflective cavity mirror, so that the laser oscillates and cavity feedback of the laser reaches a maximum, and at that point the output laser power reaches a maximum.

Step 103, remove the half-wave plate, to disable the laser light to pass through the second polarizing beam splitter 3 of the atomic optical filter, in this case the laser is deactivated again; increase the temperature of the atomic vapor cell, to enable a polarization direction of the laser light to rotate under the Faraday effect in the atomic vapor cell so that part of the laser light passes through the second polarizing beam splitter 3; where at an appropriate temperature, a transmittance of the atomic optical filter reaches a maximum, the laser is activated again, and the output power of the laser reaches the maximum.

Step 104, adjust the voltage of the piezoelectric ceramic 7, and change the cavity length of the laser, to achieve tuning of laser light, where a range of the tuning is subject to a longitudinal mode spacing of the laser, and is 680 MHz.

In this embodiment, the Faraday atomic optical filter is replaced by the Voigt anomalous dispersion atomic optical filter as a frequency-selective element, the total volume of the vapor cell and the magnets in the atomic optical filter is less than 0.1 L, which is one-fifth of the total volume of the vapor cell and the magnets in the mainstream Faraday laser, thereby the volume of the laser can be further compressed. Also, the Voigt atomic optical filter uses a magnetic field up to 4000 Gauss and has a narrower transmission bandwidth and a more stable transmission spectrum.

Thus, the Voigt laser has better frequency stability and anti-interference ability and has a wavelength change of only ±0.5 pm after long-term operation, which is lower than the wavelength change of ±2 pm of the Faraday laser after long-term operation. Also, when the current of the laser diode is changed, the wavelength change of the Voigt laser is ±0.5 pm while the wavelength change of the Faraday laser is ±2 pm. It can be seen that the Voigt laser is superior to the Faraday laser comprehensively in terms of volume, frequency stability, anti-interference ability, and other parameters.

The embodiments mentioned above are merely intended to illustrate the principles of the embodiments of the present application. In the Voigt laser, the parameter of the laser diode, the parameters such as the size of the vapor cell, the gas pressure of the buffer gas and the magnitude of the magnetic field that are in the atomic optical filter, the transmittance to reflectance ratio of the reflective cavity mirror, the travel of the piezoelectric ceramic all can be changed, which are not limited to the embodiment of the present application.

The embodiments of the present application do not impose any restrictions on the models of devices other than those otherwise specified, as long as the devices can implement the functions mentioned above.

Those skilled in the art can understand that the accompanying drawing is merely a schematic diagram of a preferred embodiment, and the serial numbers of the embodiments of the present application are merely intended for description and do not represent how well the embodiments are.

The above descriptions are merely preferred embodiments of the present application and are not intended to limit the present application. Any modifications. equivalent substitutions, improvements and so on made within the spirit and principles of the present application shall be included in the protection range of the present application.

What is claimed is:

1. An external-cavity diode laser based on a Voigt anomalous dispersion atomic optical filter, wherein the laser comprises:
a laser diode coated with an anti-reflective coating, wherein the laser diode is provided with a first temperature control apparatus thereon;
a collimation apparatus, configured to perform collimation and expanding for the laser diode;
the Voigt anomalous dispersion atomic optical filter, configured to filter laser light emitted from the laser diode, wherein a spectrum of laser light output from the laser depends on a transmission spectrum of the atomic optical filter;
a reflective cavity mirror, configured to reflect the laser light filtered by the atomic optical filter back into a resonant cavity to form oscillation and produce stable laser light;
a piezoelectric ceramic, assembled with the reflective cavity mirror and configured to fine-tune a cavity length of the laser to achieve tuning of the laser light.

2. The external-cavity diode laser based on the Voigt anomalous dispersion atomic optical filter according to claim 1, wherein the atomic optical filter comprises: two polarizing beam splitters, an alkali-metal atom vapor cell, and a magnetic field generating apparatus.

3. The external-cavity diode laser based on the Voigt anomalous dispersion atomic optical filter according to claim 1, wherein the first temperature control apparatus comprises a thermoelectric cooler (TEC) and a temperature feedback control circuit;
temperature control accuracy of the first temperature control apparatus is 0.01-0.1 degrees Celsius; the collimation apparatus is used to collimate the laser light emitted from the laser diode, to enable a divergence angle of the emitted laser light to be reduced to 0.01-2°.

4. The external-cavity diode laser based on the Voigt anomalous dispersion atomic optical filter according to claim 1, wherein the laser further comprises a laser base, four side plates and a cover plate, which are configured to fix elements in the laser and assemble respective elements into a whole.

5. The external-cavity diode laser based on the Voigt anomalous dispersion atomic optical filter according to claim 1, wherein the cavity length of the laser is a distance from an emitting end face of the laser diode to an end face of the reflective cavity mirror.

6. The external-cavity diode laser based on the Voigt anomalous dispersion atomic optical filter according to claim 2, wherein the two polarizing beam splitters are orthogonal to each other, and they are both coated with an anti-reflective coating, and have a transmittance range of 80-95% and an extinction ratio of 100:1-10000:1.

7. The external-cavity diode laser based on the Voigt anomalous dispersion atomic optical filter according to claim 2, wherein the alkali-metal atom vapor cell is further affixed with a second temperature control apparatus, which is configured to perform monitoring and feedback controlling on temperature of the alkali-metal atom vapor cell.

8. The external-cavity diode laser based on the Voigt anomalous dispersion atomic optical filter according to claim 7, wherein the second temperature control apparatus is configured to control the temperature of the alkali-metal atom vapor cell to 60-120 degrees Celsius.

9. The external-cavity diode laser based on the Voigt anomalous dispersion atomic optical filter according to claim 2, wherein the magnetic field generating apparatus comprises two rectangular neodymium iron boron permanent magnets close to a side wall of the alkali-metal atom vapor cell, and a total volume of the alkali-metal atom vapor cell and the two rectangular neodymium iron boron permanent magnets is less than 0.1 L.

10. The external-cavity diode laser based on the Voigt anomalous dispersion atomic optical filter according to claim 9, wherein the magnetic field generating apparatus is configured to generate a magnetic field with uniformity of more than 95% and magnetic field strength of more than 3500 Gauss.

11. An implementing and tuning method of an external-cavity diode laser based on a Voigt anomalous dispersion atomic optical filter, wherein the method comprises:
assembling a laser diode, a thermistor and a thermoelectric cooler onto a copper base, assembling a temperature control apparatus, a magnetic field generating apparatus, an atomic vapor cell and two polarizing beam splitters into an atomic optical filter, affixing a reflective cavity mirror and a piezoelectric ceramic to a mirror holder; installing the copper base assembled with the laser diode, the atomic optical filter, and the mirror holder assembled with the reflective cavity mirror onto a laser base;
setting polarization directions of the two polarizing beam splitters to be orthogonal, to enable output power of the laser to be close to 0;
adding a half-wave plate between the atomic vapor cell and a second polarizing beam splitter, to enable part of laser light emitted from the laser diode to pass through the second polarizing beam splitter and return along an original path at an end face of the reflecting cavity mirror, so that the laser oscillates and cavity feedback of the laser reaches a maximum;
removing the half-wave plate, to disable the laser light to pass through the second polarizing beam splitter of the atomic optical filter, increasing temperature of the atomic vapor cell, to enable a polarization direction of the laser light to rotate under Faraday effect in the atomic vapor cell so that part of the laser light passes through the second polarizing beam splitter, wherein at an appropriate temperature, a transmittance of the atomic optical filter reaches a maximum, the laser is activated again, and the output power of the laser reaches a maximum;
adjusting voltage of the piezoelectric ceramic, and changing a cavity length of the laser, to achieve tuning of laser light output from the laser.

12. The implementing and tuning method of the external-cavity diode laser based on the Voigt anomalous dispersion atomic optical filter according to claim 11, wherein the method comprises: changing a pitch of the mirror holder by pillowing a steel plate, to adjust the cavity feedback of the laser.

13. The implementing and tuning method of the external-cavity diode laser based on the Voigt anomalous dispersion atomic optical filter according to claim 11, wherein a range of the tuning is subject to a longitudinal mode spacing of the laser.

14. The implementing and tuning method of the external-cavity diode laser based on the Voigt anomalous dispersion atomic optical filter according to claim 11, further comprising:
controlling temperature of the atomic vapor cell to 60-120 degrees Celsius with the temperature control apparatus.

15. The implementing and tuning method of the external-cavity diode laser based on the Voigt anomalous dispersion atomic optical filter according to claim 11, wherein the magnetic field generating apparatus comprises two rectangular neodymium iron boron permanent magnets close to a side wall of the atomic vapor cell, and a total volume of the atomic vapor cell and the two rectangular neodymium iron boron permanent magnets is less than 0.1 L.

16. The implementing and tuning method of the external-cavity diode laser based on the Voigt anomalous dispersion atomic optical filter according to claim 15, further comprising:
controlling sizes and positions of the two rectangular neodymium iron boron permanent magnets, to generate a magnetic field with uniformity of more than 95% and magnetic field strength of more than 3500 Gauss.

17. The implementing and tuning method of the external-cavity diode laser based on the Voigt anomalous dispersion atomic optical filter according to claim 11, wherein the atomic vapor cell is an alkali-metal atom vapor cell.
